(19) United States
(12) Patent Application Publication
(10) Pub. No.: US 2025/0056830 A1
(43) Pub. Date: Feb. 13, 2025

(54) METHOD FOR PRODUCING A POWER FINFET BY MEANS OF LITHOGRAPHY MASKS, AND POWER FINFET

(71) Applicant: Robert Bosch GmbH, Stuttgart (DE)

(72) Inventors: Daniel Krebs, Aufhausen (DE); Alberto Martinez-Limia, Pliezhausen (DE); Jens Baringhaus, Sindelfingen (DE)

(21) Appl. No.: 18/716,653

(22) PCT Filed: Dec. 14, 2022
(86) PCT No.: PCT/EP2022/085803

§ 371 Date: Jul. 11, 2024

(30) Foreign Application Priority Data
Dec. 15, 2021 (DE) 10 2021 214 430.6

(51) Int. Cl. H01L 29/78; H01L 29/16; H01L 29/20; H01L 29/66

(52) U.S. Cl. CPC H01L 29/785; H01L 29/1608; H01L 29/2003; H01L 29/66734; H01L 29/66795; H01L 29/7813

(57) ABSTRACT

A method for producing a power FinFET with two-part control electrodes. The method includes: creating a first structured mask including oxide regions and first and second open regions on the front side of a semiconductor body via lithography; creating first and second trenches below the first and second open regions, respectively, by a first etching process starting from the front side of the semiconductor body into the drift layer, the first and second trenches being arranged substantially parallel to one another and alternate, the second trenches have a smaller width than the first trenches; applying a polysilicon layer onto the front side so that the first and second trenches are filled; applying an isotropic oxide layer onto the front side of the semiconductor body; creating a second structured mask on the isotropic oxide layer via lithography, wherein the second structured mask is open above the first trenches.

### FIELD

The present invention relates to a method for producing a power FinFET via lithography masks and to a power FinFET.

### BACKGROUND INFORMATION

In power electronics, semiconductors with a wide band gap, such as SiC or GaN, are used. Typically, power MOSFETs with a vertical channel region are used.

In order to increase the breakdown voltage of such power MOSFETs, shielding regions are arranged below the trenches.

Since these shielding regions are connected to the source regions, it is necessary to arrange two-part control electrodes within the trenches, as described in German Patent No. DE 10224201 B4.

This is disadvantageous in that the trenches have to be very wide so that the pitch dimension and the on-resistance of the power MOSFET are large.

Between the shielding regions, which are usually p-doped, a so-called JFET is formed between two adjacent trenches and serves to limit the current through the channel region in the event of a short circuit. For this purpose, p-doped shielding regions are implanted using a lithographically structured mask.

This is disadvantageous in that the distances between two p-doped shielding regions are exposed to process fluctuations that affect the limitation of the short-circuit current.

An object of present the present invention is to overcome these disadvantages.

### SUMMARY

A method according to an example embodiment of the present invention for producing a power FinFET with two-part control electrodes and a semiconductor body, which comprises a second connection region and a drift layer, wherein the second connection region forms a front side of the semiconductor body, comprises creating a first structured mask on the front side of the semiconductor body by means of a first lithography step, wherein the first structured mask comprises oxide regions, first open regions and second open regions, wherein the first open regions and the second open regions expose the front side of the semiconductor body; creating first trenches below the first open regions and second trenches below the second open regions by means of a first etching process starting from the front side of the semiconductor body into the drift layer, wherein the first trenches and the second trenches are arranged substantially parallel to one another and alternate, wherein the second trenches have a smaller width than the first trenches; applying a polysilicon layer onto the front side of the semiconductor body so that the first trenches and second trenches are filled; applying an isotropic oxide layer onto the front side of the semiconductor body; and creating a second structured mask on the isotropic oxide layer by means of a second lithography step, wherein the second structured mask is open above the first trenches. The method furthermore comprises removing the isotropic oxide layer above the first trenches by means of a second etching process; removing the polysilicon layer within the first trenches by means of a third etching process; and creating shielding regions below the first trenches by means of a first implantation process. Furthermore, the method comprises removing the isotropic oxide layer above the second trenches and the polysilicon layer within the second trenches by means of a fourth etching process; oxidizing the front side so that a further oxide layer is arranged on the front side; and widening the first trenches and the second trenches by means of a fifth etching process so that fins are formed between the first trenches and the second trenches, wherein the fins have a width of less than 500 nm. Furthermore, the method comprises activating the shielding regions by means of annealing; and creating two-part control electrodes within the first trenches.

This is advantageous in that the short-circuit-current-limiting effect occurs between the shielding region and the side walls of the second trenches. As a result, process fluctuations are tolerated. Although a second lithography mask is used to open the first trenches, the position of the shielding implantation is not subject to any adjustment tolerance since the position of the shielding region is defined by the trenches themselves.

In a development of the present invention, the first structured mask comprises nitride regions, wherein the oxide regions are arranged on the nitride regions.

This is advantageous in that oxidation of the fin top side is prevented.

In a further embodiment of the present invention, spreading regions below the second trenches are created by means of a second implantation process, wherein the second implantation energy has a value between 60 keV and 2500 keV.

This is advantageous in that the on-resistance is low.

In a development of the present invention, the first etching process and the second etching process are anisotropic plasma etching processes.

This is advantageous in that the structured masks can be transferred into the underlying layers with minimal widening.

In one embodiment of the present invention, the first implantation process has a first implantation energy in the range of 30 keV to 2700 keV.

This is advantageous in that the shielding regions are formed in the trench bottom below the gate oxide to be protected, so that maximum shielding effect is achieved without pitch loss.

According to an example embodiment of the present invention, the power FinFET with two-part control electrodes comprises a semiconductor body with a drift layer and a second connection region. The second connection region is arranged above the drift layer, and first trenches and second trenches extend starting from the second connection region into the drift layer. First trenches and second trenches are arranged alternately with one another, wherein the second trenches have a smaller width than the first trenches and shielding regions are arranged below the first trenches. The shielding regions directly adjoin the first trenches, wherein the shielding regions are electrically connected to source regions. One two-part control electrode is in each case arranged within the first trenches, wherein each two-part control electrode is electrically insulated from the shielding region below the first trenches. According to the present invention, fins are arranged between the first trenches and the second trenches, wherein the fins have a width of at most 500 nm.

This is advantageous in that the short-circuit current is limited by the space charge zone of the shielding regions and the opposite trench wall of a second trench. Furthermore, it is advantageous that the influence of the process variability on the short-circuit current and the on-resistance is reduced.

In a development of the present invention, spreading regions are arranged below the second trenches.

This is advantageous in that the current spreading is high and the on-resistance is low.

In a further embodiment of the present invention, the shielding regions are p-doped and have a dopant concentration of at least 1E18/cm³.

This is advantageous in that high implantation doses can be introduced cost-effectively below the trench bottom and deeper regions can be created with low implantation energies.

In one embodiment of the present invention, the semiconductor body comprises SiC.

This is advantageous in that aluminum, which is easily activatable, can be used for implantation.

In a further embodiment of the present invention, the semiconductor body comprises GaN.

This is advantageous in that the critical field strength and the electron mobility are high.

Further advantages can be found in the following description of exemplary embodiments and in the rest of the disclosure herein.

### BRIEF DESCRIPTION OF THE DRAWINGS

The present invention is explained below with reference to preferred embodiments and figures.

FIG. 1 shows a method for producing a power FinFET with two-part control electrodes, according to an example embodiment of the present invention.

FIG. 2 shows a power FinFET with two-part control electrodes, according to an example embodiment of the present invention.

### DETAILED DESCRIPTION OF EXAMPLE EMBODIMENTS

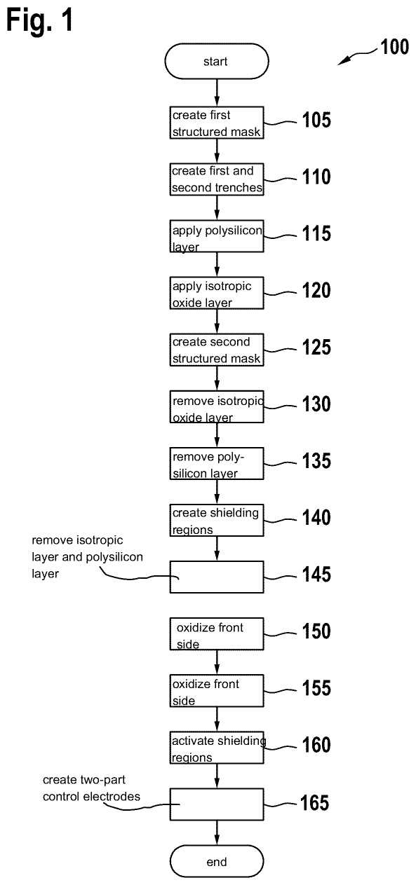

FIG. 1 shows a method for producing a power FinFET with two-part control electrodes. The power FinFET comprises a semiconductor body, which comprises SiC or GaN for example, a second connection region and a drift layer, wherein the second connection region forms a front side of the semiconductor body. The method starts with step 105, in which a first structured mask is created on the front side of the semiconductor body by means of a first lithography step. The first structured mask comprises oxide regions, first open regions and second open regions, wherein the first open regions and the second open regions expose the front side of the semiconductor body. In a subsequent step 110, first trenches below the first open regions and second trenches below the second open regions are created by means of a first etching process starting from the front side of the semiconductor body into the drift layer. In other words, the first trenches and the second trenches are created simultaneously. The first trenches and the second trenches are arranged substantially parallel to one another and alternate. The width of the second trenches is smaller than the width of the first trenches. In a subsequent step 115, a polysilicon layer is applied onto the front side of the semiconductor body so that the first trenches and second trenches are filled. In a subsequent step 120, an isotropic oxide layer is applied onto the front side of the semiconductor body. In a subsequent step 125, a second structured mask is created on the isotropic oxide layer by means of a second lithography step, wherein the second structured mask is open above the first trenches. In a subsequent step 130, the isotropic oxide layer above the first trenches is removed by means of a second etching process. In a subsequent step 135, the polysilicon layer within the first trenches is removed by means of a third etching process. In a subsequent step 140, shielding regions are created below the first trenches by means of a first implantation process. The first implantation energy is between 30 keV and 2700 keV. The shielding regions are p-doped. In a subsequent step 145, the isotropic oxide layer above the second trenches and the polysilicon layer within the second trenches are removed by means of a fourth etching process. In a subsequent step 150, the front side is oxidized so that a further oxide layer is arranged on the front side. In a subsequent step 155, the front side of the semiconductor body is oxidized so that a further oxide layer is arranged on the front side of the semiconductor body. The further oxide layer has a thickness of at least 10 nm. In a subsequent step 160, the first trenches and the second trenches are widened by means of a fourth etching process so that fins having a width of less than 500 nm are formed between the first trenches and the second trenches. The oxide from step 150 is selectively wet-chemically etched in the process. Depending on the fin width to be achieved, steps 150 and 155 are carried out cyclically. In other words, the front side of the semiconductor body is oxidized multiple times, with an etching step taking place between the oxidation steps. The widening of the trenches thus takes place without any adjustment. The lateral oxidation rate exceeds the vertical oxidation rate by approximately a factor of two. In a subsequent step 160, the shielding regions are activated by means of annealing. Annealing typically takes place at 1700° C. In a subsequent step 165, the two-part control electrodes are created within the first trenches.

By means of the method according to the present invention, the shielding regions below the first trenches are further apart from one another than the shielding regions are from the opposite trench walls or side walls of the second trenches. As a result, the short-circuit current is not limited by the space charge zones of two shielding regions abutting against one another but by the space charge zone of in each case one p-doped shielding region, which pushes or presses the current against the opposite trench wall of a second trench. The low sensitivity to the process variability is achieved in that, in the event of a short circuit, due to the positive gate voltage, the trench wall of the particular second trench forms an accumulation channel, which cannot be cleared by the space charge zone of the p-doped shielding region.

The first etching process and the second etching process are anisotropic etching processes. The fifth etching process is isotropic. In the case of a SiC semiconductor body, the first etching process selects between SiC, which is etched, and SiO2, SiN and Si, which are etched as little as possible. The second etching process etches SiO2, whereas Si is etched as little as possible. The third etching process removes Si and is very selective to SiO2, SiN and SiC, which are not etched. The fourth etching process etches SiO2 and Si but is selective to SiN and SiC, which are not etched. The fifth etching process in the case of a SiC semiconductor body selects between SiO2, which is etched, and SiC and SiN, which are not etched.

In one exemplary embodiment, the first structured mask comprises nitride regions located between the front side and the oxide regions. The nitride regions protect the front side or the surface of the fins since oxidation of the fin top side is prevented in this way in step 150. The nitride regions are removed in an intermediate step (not shown in FIG. 1) between step 155 and step 160.

In a further exemplary embodiment, spreading regions are implanted below the second trenches by means of a second implantation process. The spreading regions are n-doped and have a higher doping than the n-doped drift layer. This enhances the current spreading effect below the second trenches. The second implantation process has a second implantation energy having a value between 60 keV and 2500 keV.

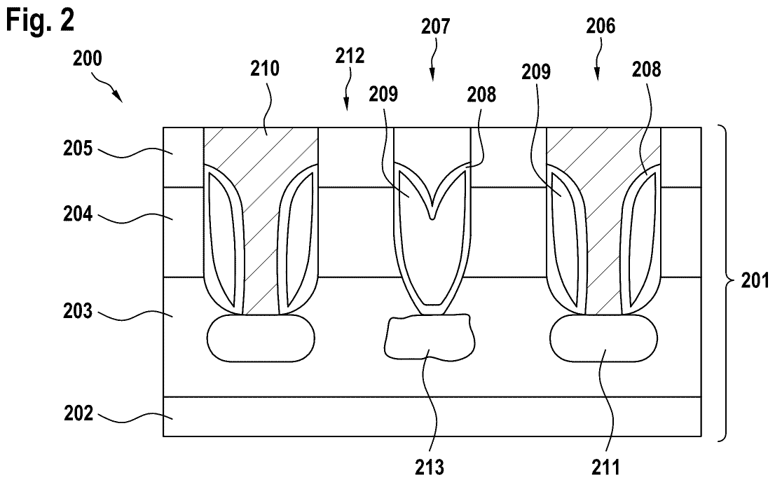

FIG. 2 shows a power FinFET 200 with two-part control electrodes 209. The power FinFET 200 comprises a semiconductor body 201, which comprises a first connection region 202, a drift layer 203, a channel region 204 and a second connection region 205. The first connection region 202 acts as a drain terminal, and the second connection region 205 acts as a source terminal. The drift layer 203 is arranged on the first connection region 202, the channel region 204 is arranged on the drift layer 203, and the second connection region 202 is arranged on the channel region 204. The second connection region 202 acts as the front side of the semiconductor body 201. Starting from the front side of the semiconductor body 201, first trenches 206 and second trenches 207 extend into the drift layer 203, wherein the second trenches 207 have a smaller width than the first trenches 206. The first trenches 206 and the second trenches 207 are arranged alternately with one another. Shielding regions 211, which are preferably p-doped, are arranged below the first trenches 206 and directly adjoin a trench bottom of the first trenches 206. The dopant concentration of the shielding regions 211 is at least 1E18/cm³. The shielding regions 211 are electrically connected to source regions 210 arranged within the trenches. Within each first trench 206, a two-part control electrode 209 is arranged, which acts as a gate terminal. The two-part control electrode 209 is electrically insulated from the shielding region 211 by means of an oxide layer 208. Fins 212 having a width of less than 500 nm are arranged between the first trenches 206 and the second trenches 207.

The semiconductor body 201 comprises SiC or GaN.

In one exemplary embodiment, spreading regions 213 are arranged below the second trenches 207. The spreading regions 213 are n-doped and have a higher doping than the drift layer 203, which is likewise n-doped.

The power FinFET is used in DC/DC converters and inverters of an electric drive train of electric or hybrid vehicles, and in vehicle chargers.

1-10. (canceled)

11. A method for producing a power FinFET with two-part control electrodes, wherein the power FinFET includes a semiconductor body, which includes a second connection region and a drift layer, wherein the second connection region forms a front side of the semiconductor body, the method comprising the following steps:
creating a first structured mask on the front side of the semiconductor body using a first lithography step, wherein the first structured mask includes oxide regions, first open regions, and second open regions, wherein the first open regions and the second open regions expose the front side of the semiconductor body;
creating first trenches below the first open regions and second trenches below the second open regions using a first etching process starting from the front side of the semiconductor body into the drift layer, wherein the first trenches and the second trenches are arranged substantially parallel to one another and alternate, and wherein the second trenches have a smaller width than the first trenches;
applying a polysilicon layer onto the front side of the semiconductor body so that the first trenches and second trenches are filled;
applying an isotropic oxide layer onto the front side of the semiconductor body;
creating second structured mask on the isotropic oxide layer using a second lithography step, wherein the second structured mask is open above the first trenches;
removing the isotropic oxide layer above the first trenches using a second etching process;
removing the polysilicon layer within the first trenches using a third etching process;
creating shielding regions below the first trenches using a first implantation process;
removing the isotropic oxide layer above the second trenches and the polysilicon layer within the second trenches using a fourth etching process;
oxidizing the front side so that a further oxide layer is arranged on the front side;
widening the first trenches and the second trenches using a fifth etching process so that fins are formed between the first trenches and the second trenches, wherein the fins have a width of less than 500 nm;
activating the shielding regions by annealing; and
creating two-part control electrodes within the first trenches.

12. The method according to claim 11, wherein the first structured mask includes nitride regions, wherein the oxide regions are arranged on the nitride regions.

13. The method according to claim 11, wherein spreading regions below the second trenches are created using a second implantation process, wherein a second implantation energy has a value between 60 keV and 2500 keV.

14. The method according to claim 11, wherein the first etching process and the second etching process are anisotropic plasma etching processes.

15. The method according to claim 11, wherein the first implantation process has a first implantation energy in a range of 30 keV to 2700 keV.

16. A power FinFET with two-part control electrodes and a semiconductor body, the power FinFET comprising:
a drift layer; and
a second connection region, wherein the second connection region is arranged above the drift layer, and first trenches and second trenches extend starting from the second connection region into the drift layer, wherein the first trenches and second trenches are arranged alternately with one another, wherein the second trenches have a smaller width than the first trenches, wherein shielding regions are arranged below the first trenches, wherein the shielding regions directly adjoin the first trenches and the shielding regions are electrically connected to source regions, wherein a two-part control electrode is arranged within each of the first trenches, wherein each two-part control electrode is electrically insulated from the shielding region below the first trenches, and fins are arranged between the first trenches and the second trenches, wherein the fins have a width of at most 500 nm.

17. The power FinFET according to claim 16, wherein spreading regions are arranged below the second trenches.

18. The power FinFET according to claim 16, wherein the shielding regions are p-doped and have a dopant concentration of at least 1E18/cm³.

19. The power FinFET according to claim 16, wherein the semiconductor body includes SiC.

20. The power FinFET according to claim 16, wherein the semiconductor body includes GaN.
